(19) United States
(12) Patent Application Publication
(10) Pub. No.: US 2021/0151299 A1
(43) Pub. Date: May 20, 2021

(54) BAFFLE UNIT AND SUBSTRATE PROCESSING APPARATUS INCLUDING THE SAME

(71) Applicant: PSK INC., Hwaseong-si (KR)

(72) Inventor: JUNG HYUN KANG, Hwaseong-si (KR)

(21) Appl. No.: 16/701,235

(22) Filed: Dec. 3, 2019

(30) Foreign Application Priority Data
Nov. 14, 2019 (KR) 10-2019-0145721

(51) Int. Cl. H01J 37/32; H01L 21/67

(52) U.S. Cl. CPC H01J 37/32633; H01J 2237/334; H01J 37/32715; H01L 21/67069

(57) ABSTRACT

The inventive concept relates to an apparatus for processing a substrate. The apparatus for processing the substrate includes a housing having a process space, a support unit that supports the substrate in the process space, a plasma source that generates plasma from a process gas, and a baffle unit disposed over the support unit. The baffle unit includes a baffle having first holes formed therein through which the process gas and/or the plasma flows, and the baffle has second holes formed in an edge region thereof, each of which has a lengthwise direction inclined with respect to a radial direction of the baffle when viewed from above.

### CROSS-REFERENCE TO RELATED APPLICATIONS

A claim for priority under 35 U.S.C. § 119 is made to Korean Patent Application No. 10-2019-0145721 filed on Nov. 14, 2019, in the Korean Intellectual Property Office, the entire contents of which are hereby incorporated by reference.

### BACKGROUND

Embodiments of the inventive concept described herein relate to a substrate processing apparatus, and more specifically, relate to a substrate processing apparatus for processing a substrate using plasma.

Plasma refers to an ionized gaseous state of matter containing ions, radicals, and electrons. The plasma is generated by heating a neutral gas to a very high temperature or subjecting a neutral gas to a strong electric field or an RF electromagnetic field. Semiconductor device manufacturing processes include an ashing or etching process of removing a thin film on a substrate by using plasma. The ashing or etching process is performed by allowing ions and radicals contained in the plasma to collide or react with the film on the substrate.

FIG. 1 is a view illustrating part of a general substrate processing apparatus. The general substrate processing apparatus 2000 includes a chamber 2100 and a baffle 2200. A process gas is supplied into the chamber 2100. The process gas supplied into the chamber 2100 is excited into a plasma state by an electromagnetic field generated in the chamber 2100. The plasma generated in the chamber 2100 passes through the baffle 2200 having a plurality of holes 2202 formed therein and is delivered to a substrate. The baffle 2200 is configured such that the plasma generated in the chamber 2100 is uniformly delivered to the substrate.

Part of the plasma generated in the chamber 2100 passes through the plurality of holes 2202 formed in the baffle 2200. Furthermore, another part of the plasma generated in the chamber 2100 collides with the baffle 2200. As the baffle 2200 is used for a long period of time, the baffle 2200 thermally deforms. The thermal deformation of the baffle 2200 occurs while the plasma collides with the baffle 2200. When the baffle 2200 thermally deforms, the baffle 2200 is warped while expanding. The baffle 2200 rises or sags in the vertical direction when warped. Due to the deformation of the baffle 2200, a clearance is generated in the area where a coupling means 2204 for coupling the baffle 2200 to the chamber 2100 is provided. When the plasma is introduced into the clearance, an arcing phenomenon may occur. The arcing phenomenon generates impurities such as particles. The generated impurities may be delivered to the substrate. The impurities delivered to the substrate hinder appropriate processing of the substrate.

### SUMMARY

Embodiments of the inventive concept provide a baffle unit for efficiently processing a substrate and a substrate processing apparatus including the baffle unit.

Embodiments of the inventive concept provide a baffle unit for minimizing generation of a clearance between a baffle and a chamber even though thermal deformation of the baffle occurs, and a substrate processing apparatus including the baffle unit.

Embodiments of the inventive concept provide a baffle unit for minimizing an arcing phenomenon and a substrate processing apparatus including the baffle unit.

Embodiments of the inventive concept provide a baffle unit for minimizing generation of impurities such as particles and a substrate processing apparatus including the baffle unit.

Embodiments of the inventive concept provide a baffle unit for providing an additional control factor in processing a substrate and a substrate processing apparatus including the baffle unit.

The technical problems to be solved by the inventive concept are not limited to the aforementioned problems, and any other technical problems not mentioned herein will be clearly understood from this specification and the accompanying drawings by those skilled in the art to which the inventive concept pertains.

According to an exemplary embodiment, an apparatus for processing a substrate includes a housing having a process space, a support unit that supports the substrate in the process space, a plasma source that generates plasma from a process gas, and a baffle unit disposed over the support unit. The baffle unit includes a baffle having first holes formed therein through which the process gas and/or the plasma flows, and the baffle has second holes formed in an edge region thereof, each of which has a lengthwise direction inclined with respect to a radial direction of the baffle when viewed from above.

According to an embodiment, a virtual straight line drawn from the center of the baffle along the radial direction may overlap at least one of the second holes when viewed from above.

According to an embodiment, the second holes may be formed in the edge region along a circumferential direction of the baffle.

According to an embodiment, the second holes may be provided in the entire edge region of the baffle.

According to an embodiment, inclined directions of the second holes may be the same.

According to an embodiment, inclination angles formed by inclined directions of the second holes and the radial direction of the baffle may be the same.

According to an embodiment, the second holes may have a long narrow hole shape.

According to an embodiment, the baffle unit may further include a cover plate disposed on the top or the bottom of the baffle, and the cover plate may have a shape that covers the second holes.

According to an embodiment, the cover plate may have a ring shape.

According to an embodiment, the cover plate may be provided to cover outer areas among inner areas and the outer areas of the second holes when viewed from above.

According to an embodiment, the cover plate may be provided to cover inner areas among outer areas and the inner areas of the second holes when viewed from above.

According to an embodiment, the cover plate may have one or more arc-shaped openings formed therein, and the openings may overlap outer areas among inner areas and the outer areas of the second holes when viewed from above.

According to an embodiment, the apparatus may include a process unit including the housing and the support unit and a plasma generation unit that includes the plasma source and that generates the plasma and supplies the generated plasma into the process space. The plasma generation unit may be disposed at the top of the process unit and may further include a plasma chamber having a plasma generation space.

According to an embodiment, the plasma generation unit may further include a diffusion chamber that is disposed at the bottom of the plasma chamber and that has a diffusion space, and the baffle unit may be coupled to the diffusion chamber.

According to an embodiment, the baffle may have a third hole formed therein into which a coupling means is inserted, and the cover plate may have a coupling hole formed therein. The coupling hole may be formed at a position corresponding to the third hole, and the coupling means may be inserted into the coupling hole.

According to an embodiment, the cover plate may be disposed on the bottom of the baffle.

According to an exemplary embodiment, a baffle unit provided in an apparatus for processing a substrate using plasma includes a baffle, when viewed from above, having first holes formed in a central region thereof and second holes formed in an edge region thereof. The plasma flows through the first holes, and each of the second holes has a lengthwise direction inclined with respect to a radial direction of the baffle.

According to an embodiment, partial areas of adjacent second holes, among the second holes, may overlap each other when viewed in the radial direction of the baffle.

According to an embodiment, the second holes may be formed in the edge region along a circumferential direction of the baffle.

According to an embodiment, the baffle unit may further include a cover plate disposed on the top or the bottom of the baffle, and the cover plate may have a ring shape to cover the second holes.

According to an embodiment, the cover plate may be provided to cover outer areas among inner areas and the outer areas of the second holes when viewed from above.

According to an embodiment, the cover plate may be provided to cover inner areas among outer areas and the inner areas of the second holes when viewed from above. The cover plate may have one or more arc-shaped openings formed therein, and the openings may overlap the outer areas when viewed from above.

According to an embodiment, the baffle may have a third hole formed therein into which a coupling means is inserted, and the cover plate may have a coupling hole formed therein. The coupling hole may be formed at a position corresponding to the third hole, and the coupling means may be inserted into the coupling hole.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating part of a general substrate processing apparatus;

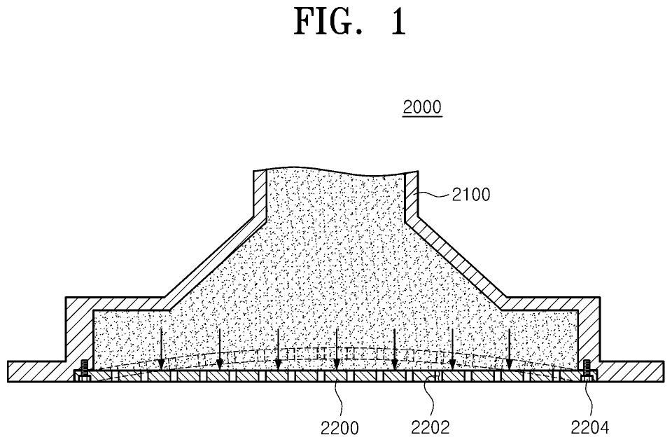

FIG. 2 is a schematic view illustrating substrate processing equipment of the inventive concept;

FIG. 3 is a view illustrating a substrate processing apparatus for performing plasma processing, among process chambers of FIG. 2;

FIG. 4 is a plan view illustrating a baffle unit according to an embodiment of the inventive concept;

FIG. 5 is a view illustrating directions in which the baffle unit of FIG. 4 is heated to thermally expand;

FIG. 6 is a view illustrating a substrate processing apparatus according to another embodiment of the inventive concept;

FIG. 7 is a view illustrating a baffle unit according to another embodiment of the inventive concept;

FIG. 8 is a view illustrating a baffle unit according to another embodiment of the inventive concept; and

FIG. 9 is a view illustrating a baffle unit according to another embodiment of the inventive concept.

### DETAILED DESCRIPTION

Hereinafter, embodiments of the inventive concept will be described in detail with reference to the accompanying drawings such that those skilled in the art to which the inventive concept pertains can readily carry out the inventive concept. However, the inventive concept may be implemented in various different forms and is not limited to the embodiments described herein. Furthermore, in describing the embodiments of the inventive concept, detailed descriptions related to well-known functions or configurations will be omitted when they may make subject matters of the inventive concept unnecessarily obscure. In addition, components performing similar functions and operations are provided with identical reference numerals throughout the accompanying drawings.

The terms “include” and “comprise” in the specification are “open type” expressions just to say that the corresponding components exist and, unless specifically described to the contrary, do not exclude but may include additional components. Specifically, it should be understood that the terms “include”, “comprise” and “have” when used herein, specify the presence of stated features, integers, steps, operations, components, and/or parts, but do not preclude the presence or addition of one or more other features, integers, steps, operations, components, parts, and/or groups thereof.

The terms of a singular form may include plural forms unless otherwise specified. Furthermore, in the drawings, the shapes and dimensions of components may be exaggerated for clarity of illustration.

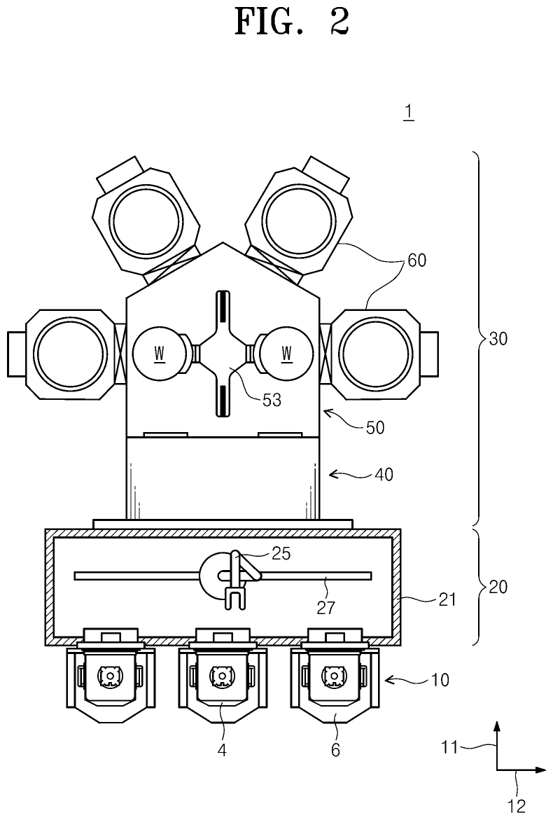

Hereinafter, embodiments of the inventive concept will be described in detail with reference to FIGS. 2 to 9.

FIG. 2 is a schematic view illustrating substrate processing equipment of the inventive concept. Referring to FIG. 2, the substrate processing equipment 1 includes an equipment front end module (EFEM) 20 and a process module 30. The equipment front end module 20 and the process module 30 are arranged in one direction.

The equipment front end module 20 includes a load port 10 and a transfer frame 21. The load port 10 is disposed in the front of the equipment front end module 20 in a first direction 11. The load port 10 includes a plurality of supports 6. The supports 6 are arranged in a row in a second direction 12, and carriers 4 (e.g., cassettes, FOUPs, or the like) in which substrates W to be processed and substrates W completely processed are received are placed on the supports 6. The substrates W to be processed and the substrates W completely processed are received in the carriers 4. The transfer frame 21 is disposed between the load port 10 and the process module 30. The transfer frame 21 includes a first transfer robot 25 that is disposed in the transfer frame 21 and that transfers the substrates W between the load port 10 and the process module 30. The first transfer robot 25 moves along a transfer rail 27 arranged in the second direction 12 to transfer the substrates W between the carriers 4 and the process module 30.

The process module 30 includes a load-lock chamber 40, a transfer chamber 50, and process chambers 60.

The load-lock chamber 40 is disposed adjacent to the transfer frame 21. For example, the load-lock chamber 40 may be disposed between the transfer chamber 50 and the equipment front end module 20. The load-lock chamber 40 provides a space in which the substrates W to be processed stand by before transferred to the process chambers 60 or a space in which the substrates W completely processed stand by before transferred to the equipment front end module 20.

The transfer chamber 50 is disposed adjacent to the load-lock chamber 40. The transfer chamber 50 has a body in a polygonal shape when viewed from above. Referring to FIG. 2, the transfer chamber 50 has a pentagonal body when viewed from above. The load-lock chamber 40 and the plurality of process chambers 60 are disposed around the body. The body has, in sidewalls thereof, passages (not illustrated) through which the substrates W enter or leave the transfer chamber 50, and the passages connect the transfer chamber 50 and the load-lock chamber 40 or the process chambers 60. Doors (not illustrated) are provided in the respective passages to open/close the passages and hermetically seal the interior of the transfer chamber 50. A second transfer robot 53 is disposed in the interior space of the transfer chamber 50 and transfers the substrates W between the load-lock chamber 40 and the process chambers 60. The second transfer robot 53 transfers unprocessed substrates W standing by in the load-lock chamber 40 to the process chambers 60, or transfers completely processed substrates W to the load-lock chamber 40. Furthermore, the second transfer robot 53 transfers a substrate W between the process chambers 60 to sequentially provide the substrate W to the plurality of process chambers 60. As illustrated in FIG. 2, when the transfer chamber 50 has the pentagonal body, the load-lock chamber 40 is disposed on the sidewall adjacent to the equipment front end module 20, and the process chambers 60 are continuously disposed on the remaining sidewalls. The transfer chamber 50 may be provided in various forms depending on required process modules, as well as in the aforementioned shape.

The process chambers 60 are disposed around the transfer chamber 50. The plurality of process chambers 60 may be provided. In the process chambers 60, processes are performed on substrates W, respectively. The process chambers 60 process the substrates W transferred from the second transfer robot 53 and provide the completely processed substrates W to the second transfer robot 53. The processes performed in the respective process chambers 60 may differ from one another. Hereinafter, among the process chambers 60, a substrate processing apparatus 1000 for performing plasma processing will be described in detail.

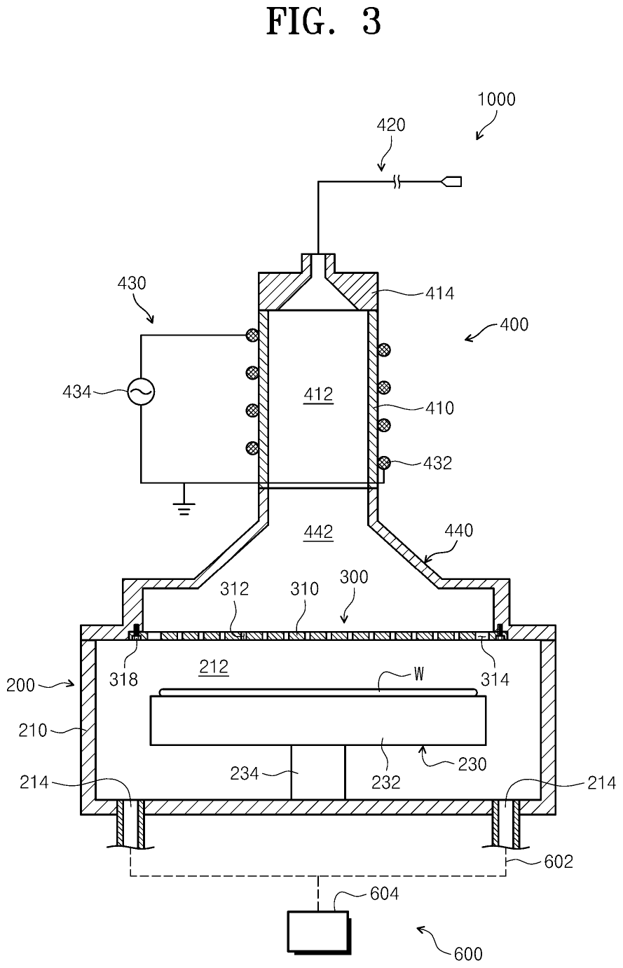

FIG. 3 is a view illustrating the substrate processing apparatus for performing plasma processing, among the process chambers of FIG. 2. Referring to FIG. 3, the substrate processing apparatus 1000 performs a predetermined process on a substrate W by using plasma. For example, the substrate processing apparatus 1000 may perform an etching or ashing process on a thin film on the substrate W. The thin film may be various types of films such as a poly silicon film, a silicon oxide film, a silicon nitride film, and the like. Alternatively, the thin film may be a native oxide film or a chemically generated oxide film.

The substrate processing apparatus 1000 may include a process unit 200, a baffle unit 300, a plasma generation unit 400, and an exhaust unit 600.

The process unit 200 provides a process space 212 in which the substrate W is placed and processed. The plasma generation unit 400 may generate plasma by exciting a process gas. The plasma generation unit 400 may supply the generated plasma into the process unit 200. The baffle unit 300 may be configured such that the plasma generated in the plasma generation unit 400 is uniformly delivered to the process space 212. The exhaust unit 600 may discharge, to the outside, the process gas remaining in the process unit 200 and/or reaction by-products generated during the substrate processing. The exhaust unit 600 may maintain the pressure in the process unit 200 at a set pressure.

The process unit 200 may include a housing 210 and a support unit 230.

The housing 210 may have the process space 212 therein in which the substrate processing is performed. The housing 210 may be open at the top thereof and may have an opening (not illustrated) that is formed in a sidewall thereof. The substrate W is placed in, or extracted from, the housing 210 through the opening. The opening may be opened or closed by an opening/closing member such as a door (not illustrated). Furthermore, exhaust holes 214 are formed in the bottom of the housing 210. The process gas and/or the reaction by-products in the process space 212 may be discharged outside the process space 212 through the exhaust holes 214. The exhaust holes 214 may be connected with components included in the exhaust unit 600 that will be described below.

The support unit 230 may support the substrate W in the process space 212. The support unit 230 may include a support plate 232 and a support shaft 234. The support plate 232 may support the substrate W in the process space 212. The support plate 232 may be supported by the support shaft 234. The support unit 232 may be connected with an external power supply and may generate static electricity by applied power. The electrostatic force of the generated static electricity may fix the substrate W to the support unit 230.

The support shaft 234 may move a target object. For example, the support shaft 234 may move the substrate W in an up/down direction. For example, the support shaft 234 may be combined with the support unit 232 and may raise or lower the support unit 232 to move the substrate W.

The baffle unit 300 may be disposed over the support unit 230. The baffle unit 300 may be disposed between the support unit 230 and the plasma generation unit 400. The baffle unit 300 may be coupled to a diffusion chamber 440 that will be described below. The baffle unit 300 may be coupled to the diffusion chamber 440 by coupling means 318. The baffle unit 300 may be configured such that the plasma generated in the plasma generation unit 400 is uniformly delivered to the substrate W. The baffle unit 300 may include a baffle 310. A detailed description of the baffle 310 will be given below.

The plasma generation unit 400 may be disposed at the top of the process unit 200. The plasma generation unit 400 may be located at the top of the housing 210. The plasma generation unit 400 may excite the process gas into plasma and may supply the generated plasma into the process space 212. The plasma generation unit 400 may include a plasma chamber 410, a gas supply unit 420, a power supply unit 430, and the diffusion chamber 440.

The plasma chamber 410 may have a shape that is open at the top and the bottom. The plasma chamber 410 may have the shape of a container that is open at the top and the bottom. The plasma chamber 410 may have a cylindrical shape that is open at the top and the bottom. The plasma chamber 410 may have a plasma generation space 412 therein. The plasma chamber 410 may be formed of a material containing aluminum oxide (Al₂O₃). The top of the plasma chamber 410 may be hermetically sealed from the outside by a gas supply port 414. The gas supply port 414 may be connected with the gas supply unit 420. The process gas may be supplied into the plasma generation space 412 through the gas supply port 414. The process gas supplied into the plasma generation space 412 may be introduced into the process space 212 through the baffle 310.

The gas supply unit 420 may supply the process gas. The gas supply unit 420 may be connected with the gas supply port 414. The process gas supplied by the gas supply unit 420 may include fluorine and/or hydrogen.

The power supply unit 430 applies RF power to the plasma generation space 412. The power supply unit 430 may be a plasma source that excites the process gas into plasma in the plasma generation space 412. The power supply unit 430 may include an antenna 432 and a power source 434.

The antenna 432 may be an inductively coupled plasma (ICP) antenna. The antenna 432 may have a coil shape. The antenna 432 may be wound around the plasma chamber 410 a plurality of times. The antenna 432 may be helically wound around the plasma chamber 410 a plurality of times. The antenna 432 may be wound around the plasma chamber 410 to correspond to the plasma generation space 412. One end of the antenna 432 may be provided at the height corresponding to an upper region of the plasma chamber 410 when viewed from the front. An opposite end of the antenna 432 may be provided at the height corresponding to a lower region of the plasma chamber 410 when viewed from the front.

The power source 434 may apply power to the antenna 432. The power source 434 may apply RF alternating current to the antenna 432. The RF alternating current applied to the antenna 432 may form an induced electric field in the plasma generation space 412. The process gas supplied into the plasma generation space 412 may obtain energy required for ionization from the induced electric field and may be converted into a plasma state. The power source 434 may be connected to the one end of the antenna 432. The power source 434 may be connected to the one end of the antenna 432 that is provided at the height corresponding to the upper region of the plasma chamber 410. The opposite end of the antenna 432 may be grounded. The opposite end of the antenna 432 that is provided at the height corresponding to the lower region of the plasma chamber 410 may be grounded. Without being limited thereto, however, the power source 434 may be connected to the opposite end of the antenna 432, and the one end of the antenna 432 may be grounded.

The diffusion chamber 440 may diffuse the plasma generated in the plasma chamber 410. The diffusion chamber 440 may be disposed at the bottom of the plasma chamber 410. The diffusion chamber 440 may have a shape that is open at the top and the bottom. The diffusion chamber 440 may have an inverted funnel shape. The upper end of the diffusion chamber 440 may have a diameter corresponding to the diameter of the plasma chamber 410. The lower end of the diffusion chamber 440 may have a larger diameter than the upper end of the diffusion chamber 440. The diffusion chamber 440 may have an increasing diameter from the upper end to the lower end thereof. The diffusion chamber 440 may have a diffusion space 442 therein. The plasma generated in the plasma generation space 412 may be diffused while passing through the diffusion space 442. The plasma introduced into the diffusion space 442 may pass through the baffle 250 and may flow into the process space 412. The baffle unit 300 may be coupled to the diffusion chamber 440. The baffle 310 included in baffle unit 300 may be coupled to the diffusion chamber 440. The baffle 310 may be coupled to the diffusion chamber 440 by the coupling means 318.

The exhaust unit 600 may discharge the process gas and impurities in the process unit 200 to the outside. The exhaust unit 600 may discharge, outside the substrate processing apparatus 1000, impurities generated during the substrate processing. The exhaust unit 600 may discharge, to the outside, the process gas supplied into the process space 212. The exhaust unit 600 may include an exhaust line 602 and a pressure reducing member 604. The exhaust line 602 may be connected with the exhaust holes 214 formed in the bottom of the housing 210. Furthermore, the exhaust line 602 may be connected with the pressure reducing member 604 that provides reduced pressure. Accordingly, the pressure reducing member 604 may reduce the pressure in the process space 212. The pressure reducing member 604 may be a pump. The pressure reducing member 604 may discharge, outside the housing 210, plasma and impurities remaining in the process space 212. Furthermore, the pressure reducing member 604 may provide reduced pressure to maintain the pressure in the process space 212 at a preset pressure.

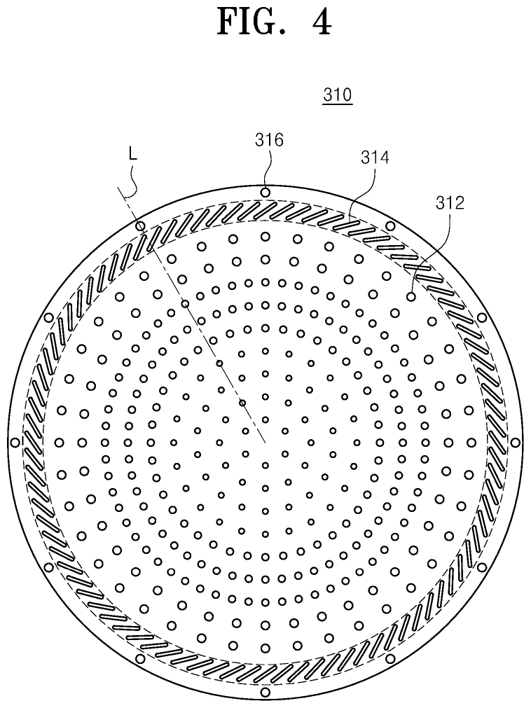

FIG. 4 is a plan view illustrating the baffle unit according to an embodiment of the inventive concept. The dash-dot-dash line or the dotted line illustrated in FIG. 4 is a virtual line represented to easily describe a configuration of the baffle 310 and does not represent the actual shape of the baffle 310. Referring to FIG. 4, the baffle 310 may have a plate shape. The baffle 310 may have a circular shape when viewed from above. The baffle 310 may have first holes 312, second holes 314, and third holes 316 formed therein.

The process gas and/or plasma may flow through the first holes 312. For example, plasma generated in the plasma generation unit 400 that will be described below may be delivered to the process unit 200 through the first holes 312. The first holes 312 may be formed in the central region of the baffle 310. The central region of the baffle 310 may refer to a region inward of the region in which the second holes 314 are formed. The plurality of first holes 312 may be provided. The first holes 312 may extend from the upper surface to the lower surface of the baffle 310. That is, the first holes 312 may be formed through the upper surface and the lower surface of the baffle 310. The first holes 312 may have a circular shape when viewed from above. The sizes and positions of the first holes 312 may be variously modified. For example, some of the first holes 312 may have a first diameter. Other first holes 312 may have a second diameter. The other first holes 312 may have a third diameter. The first diameter may be smaller than the second diameter. The second diameter may be smaller than the third diameter. For example, the first holes 312 having the first diameter may be provided in the central region of the baffle 310. The first holes 312 having the second diameter may be provided outward of the first holes 312 having the first diameter. The first holes 312 having the second diameter may be provided to surround the first holes 312 having the first diameter when viewed from above. The first holes 312 having the third diameter may be provided outward of the first holes 312 having the second diameter. The first holes 312 having the third diameter may be provided to surround the first holes 312 having the second diameter when viewed from above. The sizes, positions, and shapes of the first holes 312 may be variously modified depending on the type of the substrate W, a processing condition required to process the substrate W, or the type of the substrate processing apparatus.

The second holes 314 may be formed in the edge region of the baffle 310. The edge region of the baffle 310 may refer to a region outward of the central region in which the first holes 312 are formed. The second holes 314 may be formed in the edge region of the baffle 310 along the circumferential direction of the baffle 310. The second holes 314 may be formed in the entire edge region of the baffle 310. A virtual straight line L drawn from the center of the baffle 310 along the radial direction of the baffle 310 may overlap at least one of the second holes 314. That is, when the baffle 310 is viewed from the front in the radial direction of the baffle 310, partial areas of adjacent second holes 314, among the second holes 314, may overlap each other. The second holes 314 may have the shape of a long narrow hole. The second holes 314 may have a slit shape. The second holes 314 may extend from the upper surface of the baffle 310 to the lower surface of the baffle 310. That is, the second holes 314 may be formed through the upper surface and the lower surface of the baffle 310.

The second holes 314 may be formed in the baffle 310 so as to be inclined with respect to the radial direction of the baffle 310. The directions in which the second holes 314 are inclined with respect to the radial direction of the baffle 310 may be the same. The inclination angles formed by the inclined directions of the second holes 314 and the radial direction of the baffle 310 may be the same. The second holes 314 may form a buffer area that prevents the baffle 310 from rising or sagging in the vertical direction when thermally expanding.

The third holes 316 may be formed in the edge region of the baffle 310. The third holes 316 may be formed outward of the second holes 314. The coupling means 318 described above may be inserted into the third holes 316. The third holes 316 may be formed in the baffle 310 so as to be spaced apart from each other. The third holes 316 may be formed in the baffle 310 so as to be spaced apart from each other at constant intervals. The third holes 316 may be formed in the baffle 310 along the circumferential direction of the baffle 310.

The shapes and positions of the first holes 312, the second holes 314, and the third holes 316 formed in the baffle 310 may be variously modified. The shapes and positions of the first holes 312, the second holes 314, and the third holes 316 formed in the baffle 310 may be variously modified depending on the type of the substrate W, a processing condition required to process the substrate W, or the type of the substrate processing apparatus 1000.

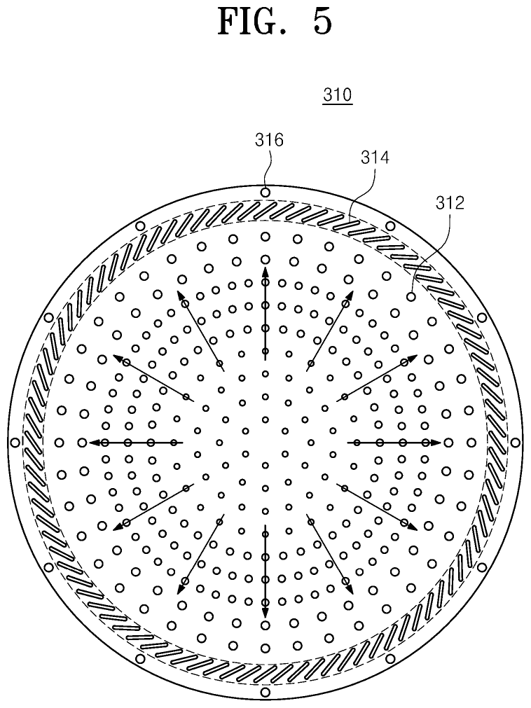

Plasma generated in the plasma generation unit 400 may pass through the baffle 310 of the baffle unit 300 and may be delivered to the process space 212. Specifically, the process gas is supplied into the plasma chamber 410. The process gas supplied into the plasma generation space 412 of the plasma chamber 410 may be excited into a plasma state by an electromagnetic field generated by the plasma source. The generated plasma may be introduced into the diffusion space 442 of the diffusion chamber 440 from the plasma generation space 412. The plasma introduced into the diffusion space 442 may be diffused. The diffused plasma may pass through the baffle 310 and may be delivered to the process space 212. The plasma may physically collide with the baffle 310 in the process of being delivered from the diffusion chamber 440 to the process space 212. Accordingly, the temperature of the baffle 310 may rise. The baffle 310 may thermally expand when the temperature of the baffle 310 rises. The baffle 310, as illustrated in FIG. 5, may expand in horizontal directions. A general baffle fails to expand in horizontal directions when thermally expanding. Accordingly, the baffle rises or sags in the vertical direction when the temperature of the baffle rises. The deformation of the baffle causes a clearance between the baffle and a chamber. When plasma is introduced into the clearance between the baffle and the chamber, an arcing phenomenon occurs. The arcing phenomenon generates impurities such as particles. The generated impurities are delivered to a substrate W and hinder appropriate processing of the substrate W.

However, according to an embodiment of the inventive concept, the baffle 310 has the plurality of second holes 314 formed in the edge region thereof. The second holes 314 form a buffer area on the baffle 310 by a combination thereof When the temperature of the baffle 310 rises, the baffle 310 more easily expands in horizontal directions because the second holes 314 form the buffer area. That is, even though the baffle 310 collides with plasma, the baffle 310 is capable of expanding in the horizontal directions, thereby minimizing generation of a clearance between the baffle 310 and the diffusion chamber 440.

Furthermore, according to an embodiment of the inventive concept, the virtual straight line L drawn from the center of the baffle 310 along the radial direction of the baffle 310 may overlap at least one of the second holes 314. That is, when the second holes 314 are viewed from the front in the radial direction of the baffle 310, partial areas of adjacent second holes 314, among the second holes 314, may overlap each other. Accordingly, even through a certain region of the baffle 310 expands, the expansion may be alleviated by at least one of the second holes 314, and therefore a problem caused by the thermal expansion of the baffle 310 may be more effectively prevented. Furthermore, the second holes 314 are inclined with respect to the radial direction of the baffle 310. The shapes and positions of the second holes 314 facilitate the expansion of the baffle 310 in the horizontal directions.

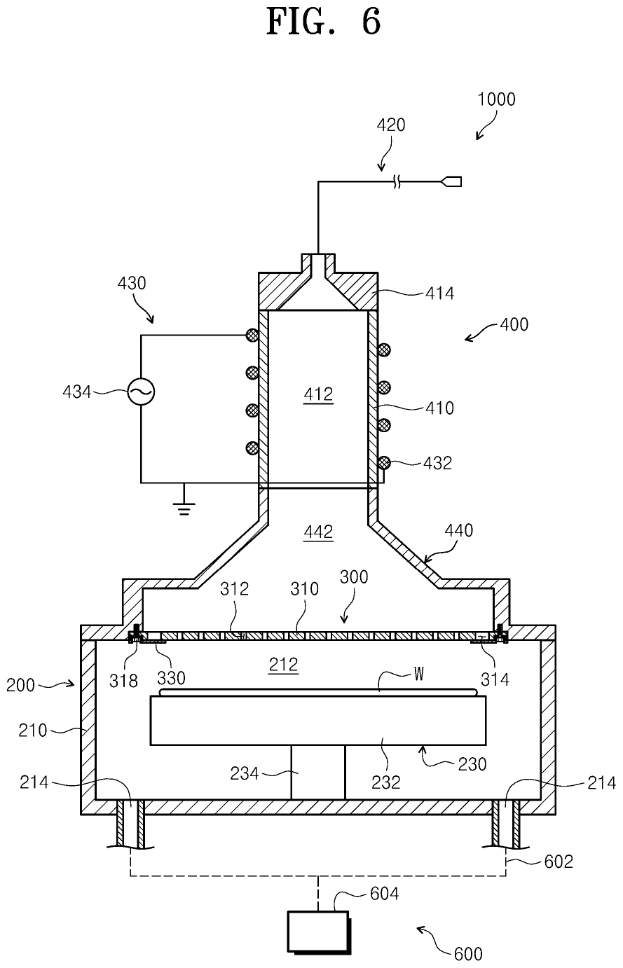

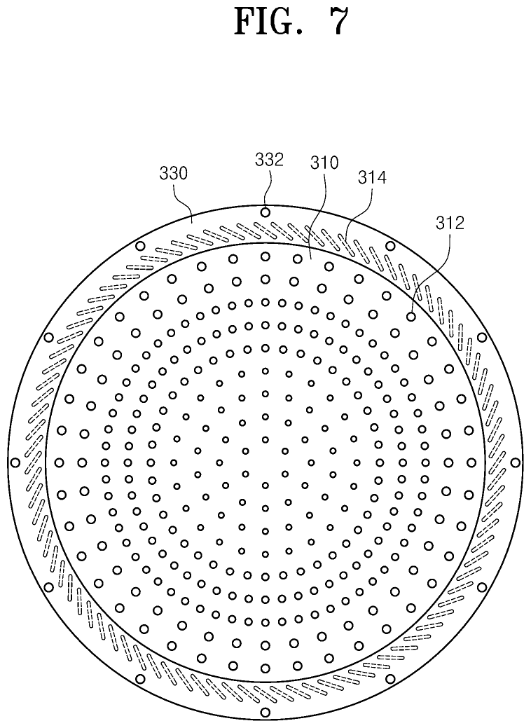

FIG. 6 is a view illustrating a substrate processing apparatus according to another embodiment of the inventive concept. FIG. 7 is a view illustrating a baffle unit according to another embodiment of the inventive concept. Referring to FIGS. 6 and 7, the baffle unit 300 may further include a cover plate 330. The cover plate 330 may be disposed on the top or the bottom of a baffle 310. For example, the cover plate 330 may be disposed on the bottom of the baffle 310. The cover plate 330 may be disposed under second holes 314. The cover plate 330 may have a shape that covers the second holes 314 of the baffle 310. For example, the cover plate 330 may have a ring shape when viewed from above. That is, when viewed from above, the entire areas of the second holes 314 may be covered by the cover plate 330. Furthermore, the cover plate 330 may have a coupling hole 332 formed therein. A plurality of coupling holes 332 may be formed in the cover plate 330. The coupling holes 332 may be formed at positions corresponding to third holes 316. The coupling holes 332 may have a shape corresponding to third holes 316. Coupling means 318 may be inserted into the coupling holes 332. That is, the coupling means 318 may be inserted into both the coupling holes 332 and the third holes 316. The cover plate 330, together with the baffle 310, may be coupled to a diffusion chamber 440 by the coupling means 318.

When the second holes 314 are formed in the baffle 310 to form a buffer area on the baffle 310, plasma generated in a plasma generation unit 400 may be delivered to a substrate W through the second holes 314. The edge region of the substrate W provided under the second holes 314 may be processed by the plasma because the second holes 314 are formed in the edge region of the baffle 310. In this case, the edge region of the substrate W may be excessively processed by the plasma. According to the other embodiment of the inventive concept, the cover plate 330 provided to completely cover the second holes 314 when viewed from above may prevent the edge region of the substrate W from being excessively processed.

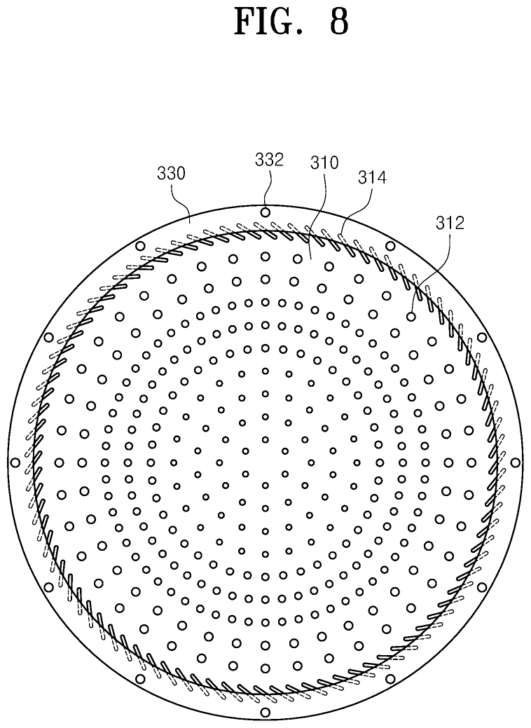

In the above-described embodiment, it has been exemplified that the entire areas of the second holes 314 are covered by the cover plate 330 when viewed from above. However, the inventive concept is not limited thereto. For example, plasma processing of the edge region of the substrate W may be further required depending on the type of the substrate W to be processed or a processing condition required to process the substrate W. Specifically, plasma processing of an inner area of the edge region of the substrate W may be required. In this case, as illustrated in FIG. 8, a cover plate 330 disposed under second holes 314 may be configured to cover only partial areas of the second holes 314. Areas where the baffle 310 is open by the second holes 314 when viewed from above may be divided into outer areas and inner areas of the second holes 314. The cover plate 330 may be provided to cover the outer areas among the outer areas and the inner areas of the second holes 314. That is, the outer areas of the second holes 314 may overlap the cover plate 330 when viewed from above. The inner areas of the second holes 314 may not overlap the cover plate 330 when viewed from above. When the cover plate 330 covers only the outer areas of the second holes 314, plasma processing may be further performed on the inner area of the edge region of the substrate W.

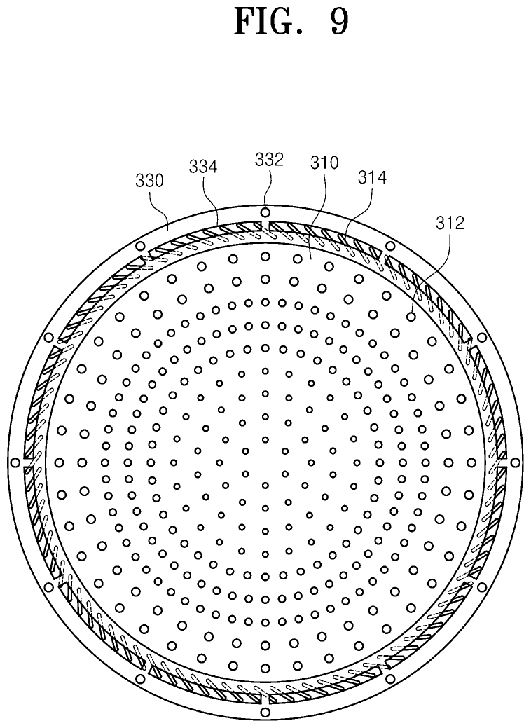

In the above-described embodiment, it has been exemplified that the entire areas of the second holes 314 are covered by the cover plate 330 when viewed from above. However, the inventive concept is not limited thereto. For example, plasma processing of the edge region of the substrate W may be further required depending on the type of the substrate W to be processed or a processing condition required to process the substrate W. Specifically, plasma processing of an outer area of the edge region of the substrate W may be required. In this case, as illustrated in FIG. 9, a cover plate 330 disposed under second holes 314 may be configured to cover only partial areas of the second holes 314. Areas where the baffle 310 is open by the second holes 314 when viewed from above may be divided into outer areas and inner areas of the second holes 314. The cover plate 330 may be provided to cover the inner areas among the outer areas and the inner areas of the second holes 314. That is, the cover plate 330 may have an opening 334 formed therein. One or more opening 334 may be formed in the cover plate 330. The openings 334 may have an arc shape. The openings 334 formed in the cover plate 330 may be provided to overlap the outer areas among the outer areas and the inner areas of the second holes 314. That is, the outer areas of the second holes 314 may overlap the openings 334 when viewed from above. Furthermore, when viewed from above, the inner areas of the second holes 314 may overlap a blocking area of the cover plate 330 in which no hole is formed. When the cover plate 330 covers only the inner areas of the second holes 314, plasma processing may be further performed on the outer area of the edge region of the substrate W.

In addition, an additional control factor for substrate processing may be provided by using the cover plates 330 illustrated in FIGS. 7 to 9. For example, the cover plates 330 coupled with the baffle 310 may be varied depending on the type of substrate W. The cover plate 330 illustrated in FIG. 7 may be defined as the first cover plate, the cover plate 330 illustrated in FIG. 8 may be defined as the second cover plate, and the cover plate 330 illustrated in FIG. 9 may be defined as the third cover plate. The first cover plate may be coupled to the baffle 310 when a first substrate is processed. The second cover plate may be coupled to the baffle 310 when a second substrate is processed. The third cover plate may be coupled to the baffle 310 when a third substrate is processed. The first to third substrates may differ from one another in terms of the types of substrates or processing conditions required for substrate processing. That is, a processing condition control factor for substrate processing may be changed by varying the types of the cover plates 330 coupled to the baffle 310.

The above-described embodiments may be variously applied to apparatuses for processing a substrate using plasma. For example, the above-described embodiments may be identically or similarly applied to various apparatuses for performing an ashing process, a deposition process, an etching process, or a cleaning process by using plasma.

As described above, according to the embodiments of the inventive concept, the baffle unit and the substrate processing apparatus may efficiently process a substrate.

According to the embodiments of the inventive concept, the baffle unit and the substrate processing apparatus may minimize generation of a clearance between the baffle and the chamber even though thermal deformation of the baffle occurs.

According to the embodiments of the inventive concept, the baffle unit and the substrate processing apparatus may minimize an arcing phenomenon in the substrate processing apparatus.

According to the embodiments of the inventive concept, the baffle unit and the substrate processing apparatus may minimize generation of impurities such as particles.

According to the embodiments of the inventive concept, the baffle unit and the substrate processing apparatus may provide an additional control factor in processing a substrate.

Effects of the inventive concept are not limited to the aforementioned effects, and any other effects not mentioned herein may be clearly understood from this specification and the accompanying drawings by those skilled in the art to which the inventive concept pertains.

The above description exemplifies the inventive concept. Furthermore, the above-mentioned contents describe the exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. An apparatus for processing a substrate, the apparatus comprising:
a housing having a process space;
a support unit configured to support the substrate in the process space;
a plasma source configured to generate plasma from a process gas; and
a baffle unit disposed over the support unit,
wherein the baffle unit includes a baffle having first holes formed therein through which the process gas and/or the plasma flows, and
wherein the baffle has second holes formed in an edge region thereof, each of which has a lengthwise direction inclined with respect to a radial direction of the baffle when viewed from above.

2. The apparatus of claim 1, wherein a virtual straight line drawn from the center of the baffle along the radial direction overlaps at least one of the second holes when viewed from above.

3. The apparatus of claim 1, wherein the second holes are formed in the edge region along a circumferential direction of the baffle.

4. The apparatus of claim 3, wherein the second holes are provided in the entire edge region of the baffle.

5. The apparatus of claim 1, wherein inclined directions of the second holes are the same.

6. The apparatus of claim 1, wherein inclination angles formed by inclined directions of the second holes and the radial direction of the baffle are the same.

7. The apparatus of claim 1, wherein the second holes have a long narrow hole shape.

8. The apparatus of claim 1, wherein the baffle unit further includes a cover plate disposed on the top or the bottom of the baffle, and
wherein the cover plate has a shape that covers the second holes.

9. The apparatus of claim 8, wherein the cover plate has a ring shape.

10. The apparatus of claim 9, wherein the cover plate is provided to cover outer areas among inner areas and the outer areas of the second holes when viewed from above.

11. The apparatus of claim 9, wherein the cover plate is provided to cover inner areas among outer areas and the inner areas of the second holes when viewed from above.

12. The apparatus of claim 9, wherein the cover plate has one or more arc-shaped openings formed therein, and
wherein the openings overlap outer areas among inner areas and the outer areas of the second holes when viewed from above.

13. The apparatus of claim 8, wherein the apparatus comprises:
a process unit including the housing and the support unit; and
a plasma generation unit including the plasma source, the plasma generation unit being configured to generate the plasma and supply the generated plasma into the process space, and
wherein the plasma generation unit is disposed at the top of the process unit and further includes a plasma chamber having a plasma generation space.

14. The apparatus of claim 13, wherein the plasma generation unit further comprises a diffusion chamber disposed at the bottom of the plasma chamber and having a diffusion space, and
wherein the baffle unit is coupled to the diffusion chamber.

15. The apparatus of claim 14, wherein the baffle has a third hole formed therein into which a coupling means is inserted, and
wherein the cover plate has a coupling hole formed therein, the coupling hole being formed at a position corresponding to the third hole, wherein the coupling means is inserted into the coupling hole.

16. The apparatus of claim 15, wherein the cover plate is disposed on the bottom of the baffle.

17. A baffle unit provided in an apparatus for processing a substrate using plasma, the baffle unit comprising:
a baffle, when viewed from above, having first holes formed in a central region thereof and second holes formed in an edge region thereof, wherein the plasma flows through the first holes, and each of the second holes has a lengthwise direction inclined with respect to a radial direction of the baffle.

18. The baffle unit of claim 17, wherein partial areas of adjacent second holes, among the second holes, overlap each other when viewed in the radial direction of the baffle.

19. The baffle unit of claim 17, wherein the second holes are formed in the edge region along a circumferential direction of the baffle.

20. The baffle unit of claim 17, wherein the baffle unit further comprises a cover plate disposed on the top or the bottom of the baffle, and
wherein the cover plate has a ring shape to cover the second holes.

21. The baffle unit of claim 20, wherein the cover plate is provided to cover outer areas among inner areas and the outer areas of the second holes when viewed from above.

22. The baffle unit of claim 20, wherein the cover plate is provided to cover inner areas among outer areas and the inner areas of the second holes when viewed from above,
wherein the cover plate has one or more arc-shaped openings formed therein, and
wherein the openings overlap the outer areas when viewed from above.

23. The baffle unit of claim 20, wherein the baffle has a third hole formed therein into which a coupling means is inserted, and
wherein the cover plate has a coupling hole formed therein, the coupling hole being formed at a position corresponding to the third hole, wherein the coupling means is inserted into the coupling hole.
